(19) United States
(12) Patent Application Publication
(10) Pub. No.: US 2011/0006278 A1
(43) Pub. Date: Jan. 13, 2011

(54) VARIABLE RESISTANCE NON-VOLATILE MEMORY DEVICE AND METHOD FOR MANUFACTURING THE SAME

(76) Inventor: Kensuke Takahashi, Tokyo (JP)

Correspondence Address: Mr. Jackson Chen, 6535 N. STATE HWY 161, IRVING, TX, 75039, US

(21) Appl. No.: 12/864,565

(22) PCT Filed: Jan. 26, 2009
(86) PCT No.: PCT/JP2009/051204

§ 371 Date: Jul. 26, 2010

(30) Foreign Application Priority Data
Jan. 28, 2008 (JP) 2008-016240

(51) Int. Cl. H01L 45/00; H01L 21/16

(52) U.S. Cl. 257/4; 438/104; 257/E21.078; 257/E45.003

(57) ABSTRACT

A variable resistance non-volatile memory device of the laminated structure of an upper electrode a variable resistance material a lower electrode includes an insulating film formed for being contacted with the variable resistance material and a reset electrode formed for being contacted with the insulating film without being contacted with the upper electrode or the lower electrode. The device is reset by applying a voltage to the reset electrode. A low resistance value for the set state and a high resistance value for the reset state may be obtained as the current during the reset operation of the device is reduced. A low reset current and a high resistance ratio between the resistance value for the set state and that for the reset state are simultaneously achieved.

### REFERENCE TO RELATED APPLICATION

This application is the National Phase of PCT/JP2009/051204, filed Jan. 26, 2009, which is based upon and claims the benefit of the priority of Japanese patent application No. 2008-016240 filed on Jan. 28, 2008, the disclosure of which is incorporated herein in its entirety by reference thereto.

### TECHNICAL FIELD

This invention relates to a non-volatile MIM (metal-insulator-metal) memory device, and to a method for manufacture thereof.

### BACKGROUND ART

The non-volatile memory, which has become a mainstream device in the marketplace, is implemented using a technique of varying a threshold value voltage of a semiconductor transistor by an electric charge accumulated within the bulk of an insulating film arranged above a channel region. Representative examples of such non-volatile memory include a flash memory and a SONOS (silicon-oxide-nitride-oxide-silicon) memory. To achieve a large storage capacity, the miniaturization of a transistor is indispensable. However, if the insulating film which is for holding the electric charge, is reduced in thickness, the charge holding capability is lowered due to the increased leakage current. It is thus becoming difficult to increase the storage capacity of the charge storage transistor type non-volatile memory.

For this reason, researches are being conducted in a line of having a transistor take charge only of a switching function of selecting read/write memory cells, and separating the transistor from a memory element, as in the case of a DRAM (Dynamic Random Access Memory). The transistor and the memory element are individually miniaturized in order to persist in the effort of enlarging the storage capacity. By way of a technique that allows for miniaturization of the non-volatile memory function, development of a variable resistance device, comprised of an electrical element whose electrical resistance value is switched between two or more values by some electrical stimulus or other, is going on briskly. The reason may be such that, with a memory of the type in which electric charges are accumulated in a capacitance, such as a DRAM, an electrical resistance may be of a finite value, even on miniaturization, in contradistinction from the signal voltage that is inevitably lowered with decrease in the accumulated electric charges brought about by miniaturization. Thus, if such a material whose electrical resistance may be varied as described above, or the principle that allows for such variation of the resistance value, is made available, the variable resistance device is thought to be beneficial in keeping on the effort towards miniaturization. The operation of the variable resistance device is that of a switch that changes over from a set state (ON state) to a reset state (OFF state), and may, for example, be applied to a switching device (selector) used for switching between different interconnections within an LSI, insofar as the operating principle is concerned.

There are several known techniques that allow for changing the electrical resistance by application of electrical stimuli. Of these, the technique researched most energetically at present is a memory device generally termed a ‘phase change memory’. With this memory device, the pulse current is caused to flow through a chalcogenide semiconductor to switch between different crystal states, specifically, between a crystalline phase and an amorphous phase. The fact that the electrical resistance of one of the crystal phases differs by two to three orders of magnitude from that of the other crystal state is utilized.

It has also been known that a metal/metal oxide/metal structure, formed by sandwiching a metal oxide in-between the electrodes, which is referred to below as a “MIM type”, similarly undergoes a resistance change, when a large voltage or current is applied thereto.

During 1950's and 1960's, researches and reports have been made on the phenomenon in which, in a variety of materials, the resistance value is varied by the voltage or current. For example, a report has been made in Patent Document 1 of a variable resistance device that uses nickel oxide (NiO).

FIG. 1 is a diagram schematically showing the cross-section of a MIM variable resistance device. A metal oxide 2, for example, a NiO layer, is sandwiched between an upper electrode 1 and a lower electrode 3.

FIG. 2A shows a current-to-voltage characteristic of a MIM type variable resistance device. This device may keep its high resistance OFF state or low resistance ON state in a non-volatile manner, even on power off. However, the resistance states of the device may be switched by applying a predetermined voltage and current stimuli as necessary. FIG. 2A shows a typical current to voltage characteristic of the ON and OFF states, in which a voltage applied is plotted on the horizontal axis and a current is plotted in log scale on the vertical axis. If a set voltage of Vt2 is applied to the device in a high resistance OFF state, as indicated by a dashed line in FIG. 2A, the state of the device is turned into a low-resistance ON state. Thus, an electrical characteristic indicated by a solid line in FIG. 2A is displayed.

If the reset voltage of Vtl is applied to the device in the ON state, as indicated by a solid line in FIG. 2A, the state of the device is turned into a high-resistance OFF state to return to the electrical characteristic indicated by the dashed line in FIG. 2A.

The electrical characteristic may repeatedly be switched between that shown by the dashed line and that shown by the solid line in FIG. 2A. This property may be utilized as a non-volatile memory cell or a non-volatile switch for circuit switching.

In general, the phase-change memory undergoes a drastic volume change accompanying a change in the crystalline phase. In addition, heating to a few hundreds of degrees centigrade is locally required to cause such change in the crystalline phase, even granting that the heating is of a short duration of a few tens of nanoseconds.

Thus, if the device is used as a memory device or a switch, such a problem is met that the temperature control of the phase change material is difficult.

On the other hand, the MIM variable resistance material has recently drawn attention again since it is unnecessary to heat it to a temperature as high as a few hundreds of degrees centigrade. Thus, a variable resistance memory device, employing an oxide of a transition metal, such as Cu, Ti, Ni, Cu or Mo, as a variable resistance material, has been proposed.

As regards the variable resistance characteristic of these transition metal oxides, it has been reported that a current path 4, termed a filament, is formed in the transition metal oxide 2, as shown in FIG. 3. A change in the electrical resistance is produced as a result of connection and disconnection of the current path 4 to and from the upper and lower electrodes 1 and 3.

In Patent Document 1 and in Non-Patent Document 2, for example, there are disclosed a variable resistance memory device employing a nickel oxide as a metal oxide layer. Non-Patent Document 2 states that a current path, termed a filament, shown in FIG. 3, is generated in the nickel oxide. The resistance of the device is varied in dependence on the connection state of the current path to the upper and lower electrodes.

### Patent Document 1:

JP Patent Kokai Publication No. JP-P2006-210882A

### Non-Patent Document 1:

Solid State Electronics, Vol. 7, pp. 785-797, 1964

### Non-Patent Document 2:

Applied Physics Letters, Vol. 88, pp. 202102, 2006

### SUMMARY

The disclosures of the above Non-Patent Documents 1 and 2 and Patent Document 1 are to be incorporated herein by reference. The following is an analysis of the related techniques by the present invention.

The above mentioned related techniques have been found to have the following problems.

(1) The first problem is that, since the MIM variable resistance device is a two-terminal device, the current flowing at the time of the set/reset operations is difficult to control.

As may be seen from FIG. 2A, in the set operation, the operating state of the device transfers to an ON state under a high voltage condition. Hence, a large current may flow suddenly, thus possibly destructing the circuit.

Also, in the reset operation, a large current flows inevitably, when the device transferring to the OFF state. In this case, there is a possibility that the large current flows to destruct the circuit.

If a mechanism for current limitation is provided in advance, as shown in FIG. 2B, it is possible to prevent that the large current flows during the set time to destruct the circuit.

On the other hand, during the reset time, the device is already in the low resistance state. Thus, if the current limitation is set, the voltage necessary for resetting may not be applied, thus disabling the resetting.

If the variable resistance material or the current limitation during the reset operation is optimized, as indicated by a thin solid line in FIG. 2B, the reset current may be reduced by setting the resistance value in the ON state to a higher value to reduce the ON current. However, in this case, the ratio of the resistance in the ON state and that in the OFF state becomes smaller, and hence the device may cease to operate stably.

(2) The second problem is that a transition metal oxide tends to suffer from defects, such as oxygen-deficiency or metal-deficiency.

These defects may be the cause of formation of leakage current paths. That is, if there are many defects in a film, and a device is operated in a number of times, new defects are produced in the variable resistance material due to the leakage current. The value of the leakage current increases further and the resistance value in the OFF state keeps on to be reduced. As a result, the lowering of the ratio of the resistance in the ON state and that in the OFF state and the variation in the device characteristic are produced to deteriorate device reliability.

The present invention has been invented based on the recognition of the above problems of the related art. It is an object of the present invention to provide a semiconductor memory device and a manufacturing method thereof, in which a reset current may be reduced and lowering of a ratio of a resistance in an ON state to that in an OFF state (set/reset resistance ratio) can be suppressed.

The invention may be summarized substantially as follows, though not limited thereto:

According to the present invention, there are provided a MIM type device structure and a manufacturing method of a variable resistance material in which, in a MIM type variable resistance device, the reduction of a resistance value in an ON state can be comparable with the reduction of a current needed for the reset operation, and with control of the generation of defects in a film the performance as well as reliability of the device can be improved. According to the present invention, there is provided a variable resistance non-volatile semiconductor memory device with a laminated structure of an upper electrode/variable resistance material/lower electrode in which the variable resistance material is sandwiched between metal electrodes, including an insulating film formed for being contacted with the variable resistance material and a reset electrode formed for being contacted with this insulating film without being contacted with the upper electrode or with the lower electrode. This reset electrode may be formed of metal. The variable resistance material may include a transition metal oxide and, preferably, an oxide of a metal selected from the group consisting of Ni, Ti, Zr, Fe, V, Mn and Co. More preferably, the transition metal oxide is Ni oxide. This Ni oxide may be mono-crystalline, poly-crystalline or amorphous, preferably amorphous. Assuming that the composition of the Ni oxide is expressed as NiₓO₁₋ₓ, where 0<X<1, X may be such that 0.42<X<0.49. The density of atoms of the Ni oxide may be in a range of 5.0 to 6.3 g/cm³.

In one aspect, there is provided a variable resistance device according to the present invention includes:

first and second electrodes arranged spaced apart from each other;

a variable resistance material including a transition metal oxide as a main component, the variable resistance material arranged to have at least one surface thereof and the other surface thereof opposite to the one surface contacted with opposing surfaces of the first electrode and the second electrode, respectively;

an insulating film arranged on the variable resistance material at a location thereof different from respective locations thereof on which the first and second electrodes are arranged, the insulating film contacted with the variable resistance material; and

a reset electrode arranged on a side of the insulating film opposite to a side thereof contacted with the variable resistance material.

According to the present invention, the first electrode may be a lower electrode formed on a semiconductor substrate or an insulator substrate. The variable resistance material may be formed on the lower electrode, and the second electrode may be formed on the variable resistance material.

According to the present invention, the insulating film may be arranged on a location of the opposite side surface of the variable resistance material different from a site thereof where the second electrode is arranged. The reset electrode may be arranged on the insulating film.

According to the present invention, the insulating film may be arranged in at least a partial region of a lateral surface of the variable resistance material.

According to the present invention, the second electrode may be contacted with the variable resistance material both on a surface of the second electrode parallel to the surface of the first electrode contacted with the variable resistance material and on a surface of the second electrode perpendicular thereto. The variable resistance material may be contacted with the insulating film on a surface perpendicular to a junction surface of the variable resistance material and the first electrode. The reset electrode may be contacted with a surface of the insulating film opposite to the surface of the insulating film contacted with the variable resistance material.

According to the present invention, the variable resistance material may have a recess on its opposite surface side with respect to the above mentioned one surface, with the bottom of the recess contacting with the bottom of the second electrode. An inner wall surface of the recess may be contacted with at least a part of a lateral surface of the second electrode. At least one part of the lateral surface of the variable resistance material may carry the above mentioned insulating film. The at least one part of a lateral surface of the variable resistance material may carry the insulating film. The surface of the insulating film opposite to its side contacted with the variable resistance material may carry the reset electrode.

According to the present invention, the transition metal oxide may include an oxide of at least one metal selected from the group consisting of Ni, Ti, Zr, Fe, V, Mn and Co.

According to the present invention, the transition metal oxide may include Ni oxide.

According to the present invention, in case the composition of the Ni oxide is represented by NiₓO₁₋ₓ (0<X<1), X may be in a range of 0.42<X<0.49.

According to the present invention, the atomic density of the Ni oxide may be in a range of 5.0 to 6.3 g/cm³.

In another aspect of the present invention, there is provided a method for manufacturing a variable resistance device, the method including:

forming a variable resistance material, including a transition metal oxide, on a first electrode, and forming a second electrode on the variable resistance material;

forming an insulating film on the variable resistance material at a location thereof different from respective locations thereof on which the first and second electrodes are arranged, the insulating film having one side contacted with the variable resistance material; and

forming a reset electrode on a side of the insulating film opposite to the one side thereof contacted with the variable resistance material.

According to the present invention, the insulating film may be formed in at least a partial region of the lateral surface of the variable resistance material.

According to the present invention, the second electrode may be formed for being contacted with the variable resistance material on a surface parallel to the surface of contact of the variable resistance material with the first electrode and on a surface perpendicular thereto.

The insulating film may be formed for being contacted with the variable resistance material on a surface perpendicular to a junction surface of the variable resistance material with the first electrode.

The reset electrode may be formed for being contacted with a surface of the insulating film opposite to its surface side contacted with the variable resistance material.

A method for manufacturing a variable resistance device, in a further aspect of the present invention includes the steps of:
(a) depositing a first electrode material, a variable resistance material including a transition metal oxide as a main component, and a second electrode material in this order on a substrate, and processing the first electrode material, the variable resistance material and the second electrode material to a predetermined shape;
(b) removing a part of the second electrode material to expose the surface of the variable resistance material, depositing an insulating film on the exposed surface of the variable resistance material and depositing a reset electrode material on the insulating film; and
(c) processing the reset electrode material to form a reset electrode at least in a partial region corresponding to the removed part of the second electrode material on the insulating film.

A method for manufacturing a variable resistance device, in a further aspect of the present invention, includes the steps of:
(a) depositing a first electrode material, a variable resistance material including a transition metal oxide as a main component, and a second electrode material in this order on a substrate, and processing the first electrode material, the variable resistance material and the second electrode material to a predetermined shape;
(b) depositing an insulating film for covering at least a lateral surface of the first electrode material, a lateral surface of the variable resistance material, a lateral surface of the second electrode material and a surface of the second electrode material_{;} and further depositing a reset electrode material thereon; and
(c) removing the reset electrode material and the insulating film on the second electrode material to form an opening to expose the second electrode material.

A method for manufacturing a variable resistance device, in a further aspect of the present invention, includes the steps of:
(a) forming a first electrode material on a substrate and processing the first electrode material to a predetermined shape;
(b) depositing a first insulating film and a reset electrode material to cover the first electrode material, and forming a second insulating film thereon;
(c) providing an opening in the second insulating film on the first electrode material, in the first insulating film and in the reset electrode material to expose the first electrode material;
(d) forming a third insulating film on a sidewall of the opening;
(e) forming a variable resistance material including a transition metal oxide as a main component, in contact with an exposed surface of the first electrode material in a bottom of the opening and with the third insulating film on a sidewall of the opening; and filling a second electrode material on the variable resistance material in the opening.

In the method for manufacturing a variable resistance device according to the present invention, a via may be formed for connecting to the second electrode material, and another via may also be formed for connecting to the reset electrode.

In the method for manufacturing a variable resistance device according to the present invention, the first electrode material may be formed on a planarized surface of a via interconnect connecting to the first electrode material on the substrate, and on an interlayer insulating film.

In the method for manufacturing a variable resistance device according to the present invention, the transition metal oxide may include an oxide of at least one metal selected from the group consisting of Ni, Ti, Zr, Fe, V, Mn and Co.

In the method for manufacturing a variable resistance device according to the present invention, the transition metal oxide may include Ni oxide.

In the method for manufacturing a variable resistance device according to the present invention, in case the composition of the Ni oxide is represented by NiₓO₁₋ₓ (0<X<1), X may be in a range of 0.42<X<0.49.

In the method for manufacturing a variable resistance device according to the present invention, the atomic density of the Ni oxide may be in a range of 5.0 to 6.3 g/cm³.

In further aspect of the present invention, there is provided a method for operating a variable resistance semiconductor memory device of a laminated structure including a first electrode, a variable resistance material and a second electrode, wherein an insulating film is formed for being contacted with a part of the variable resistance material, the method comprising:

applying a predetermined voltage to a reset electrode formed for being contacted with a part of a surface of the insulating film opposite to another surface thereof contacted with the variable resistance material, the reset electrode not formed for being contacted with the first electrode or with the second electrode.

According to the present invention, it is possible to reduce the current needed for resetting as well as to suppress that the ratio of the resistance for the ON state and that for the OFF state (set/reset resistance ratio) is decreased.

Still other features and advantages of the present invention will become readily apparent to those skilled in this art from the following detailed description in conjunction with the accompanying drawings wherein only exemplary embodiments of the invention are shown and described, simply by way of illustration of the best mode contemplated of carrying out this invention. As will be realized, the invention is capable of other and different embodiments, and its several details are capable of modifications in various obvious respects, all without departing from the invention. Accordingly, the drawing and description are to be regarded as illustrative in nature, and not as restrictive.

### BRIEF DESCRIPTION OF THE DRAWINGS

FIG. 1 is a schematic cross-sectional view showing a typical cross-section of a MIM variable resistance device.

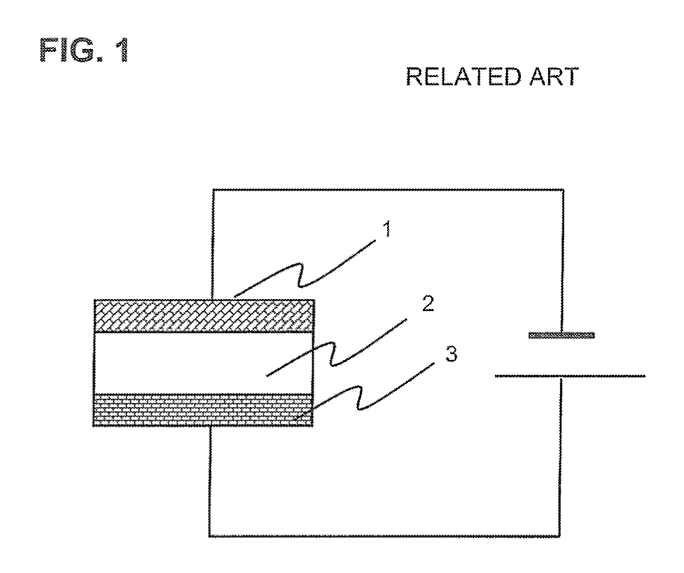

FIGS. 2A and 2B are graphs showing basic resistance variation characteristics of a MIM variable resistance device in which a nickel oxide is used as a variable resistance material.

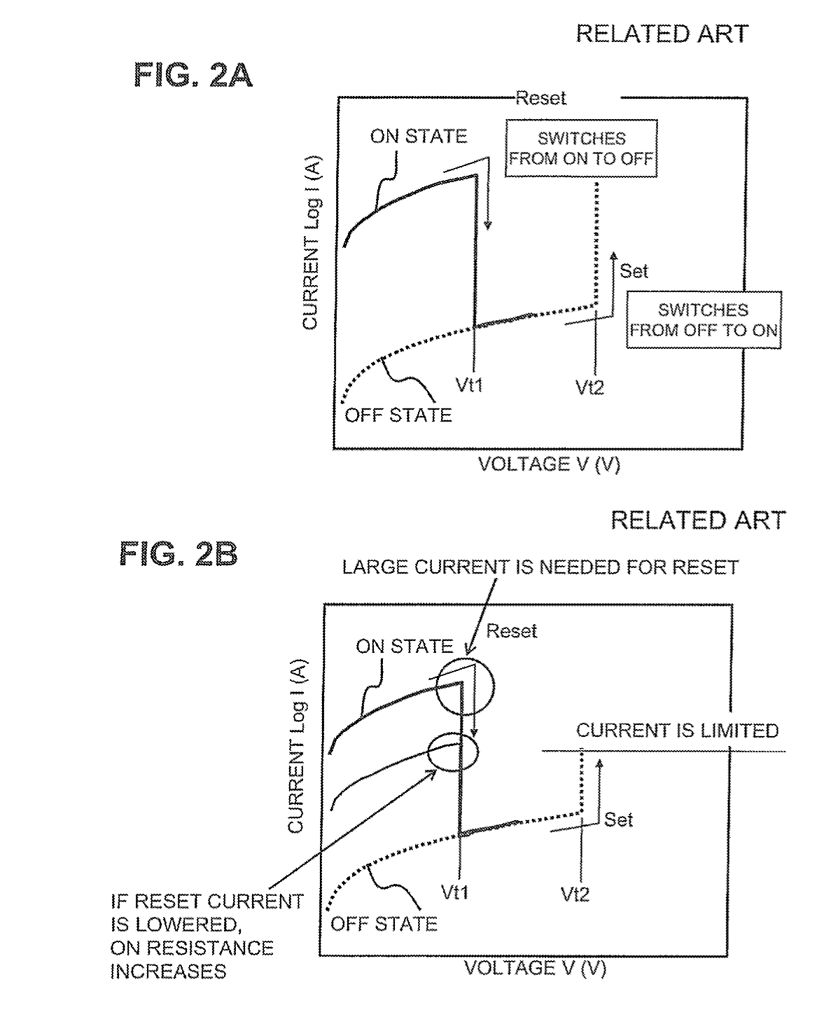

FIG. 3 is a see-through perspective view of a MIM variable resistance device showing the process of formation of a local current path that takes charge of an ON state.

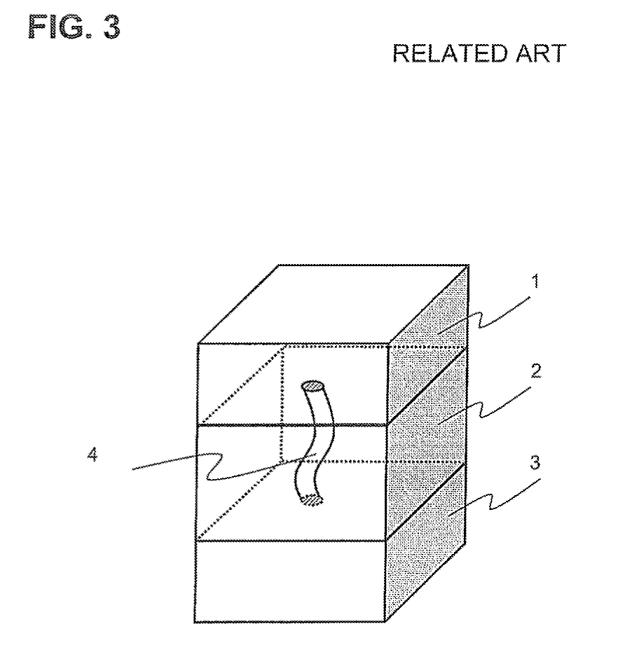

FIGS. 4A and 4B are schematic cross-sectional views showing the process of formation of a local current path that takes charge of an ON state of the MIM variable resistance device.

FIG. 5 schematically shows a cross-section of a MIM variable resistance device according to an exemplary embodiment of the present invention.

FIGS. 6A to 6C schematically show the principle of the operation of a MIM variable resistance device according to the exemplary embodiment of the present invention.

FIG. 7 is a graph showing an example relationship between the composition and the density of the nickel oxide used in the exemplary embodiment of the present invention.

FIGS. 8A and 8B are graphs showing typical composition dependency of the ON/OFF resistance ratio of the nickel oxide used in the exemplary embodiment of the present invention and the set voltage.

FIG. 9 is a graph showing typical deposition temperature dependency of the density of the nickel oxide used in the exemplary embodiment of the present invention.

FIGS. 10A to 10H are schematic cross-sectional views showing essential steps of the manufacturing process of the MIM variable resistance device according to Example 1 of the present invention.

FIGS. 11A to 11G are schematic cross-sectional views showing essential steps of the manufacturing process of a MIM variable resistance device according to Example 2 of the present invention.

FIGS. 12A to 12C illustrate the operation principle of the MIM variable resistance device according to Example 2 of the present invention.

FIGS. 13A to 13J are schematic cross-sectional views showing essential steps of the manufacturing process of a MIM variable resistance device according to Example 3 of the present invention.

FIGS. 14A to 14C illustrate the operation principle of the MIM variable resistance device according to Example 3 of the present invention.

### PREFERRED MODES

Exemplary embodiments of the present exemplary embodiment will now be described. In accordance with one of preferred modes of the present invention, there is provided a variable resistance non-volatile memory device (MIM type device) having a metal/variable resistance material/metal structure in which a variable resistance material (2) is sandwiched between metal electrodes (1, 3). An insulating film (6) is provided for being contacted with the variable resistance material (2). A voltage is applied to a reset electrode (7) which adapted for being contacted with the insulating film (6) without being contacted with the upper electrode (1) or with the lower electrode (3). By so doing, the MIM type device may be reset as scarcely any current is caused to flow. In addition, the current needed for the reset operation may be decreased without deteriorating the on/off resistance ratio in the switching operation of the MIM type device.

In one of preferred modes of the present invention, a NiO film, for example, is used for the variable resistance material (2). Assuming that the composition of the NiO film is expressed by NiₓO₁₋ₓ, where 0<X<1, the composition ratio X for Ni may be set so that 0.42<X<0.49. The density of atoms may be set in a range of 5.0 to 6.3 g/cm³. By so doing, it becomes possible to improve controllability of filament formation and to suppress the leakage current which is caused to flow by defects in the film, thus providing for a high ratio of on/off resistance and improving long-term reliability simultaneously.

The present invention is based on the following novel findings: In a variable resistance non-volatile memory device, having a metal/variable resistance material/metal structure in which a variable resistance material (2) is sandwiched between metal electrodes (1, 3), the phenomenon of variations of the resistance value of the variable resistance material (2) originates from deficiencies of oxygen or metal contained in a transition metal oxide constituting the variable resistance material (2). Specifically, oxygen or metal is diffused or precipitated under an electric field applied to the transition metal oxide, via the oxygen deficiency or metal deficiency contained in the transition metal oxide, as a result of which a current path (filament) is generated in the transition metal oxide film.

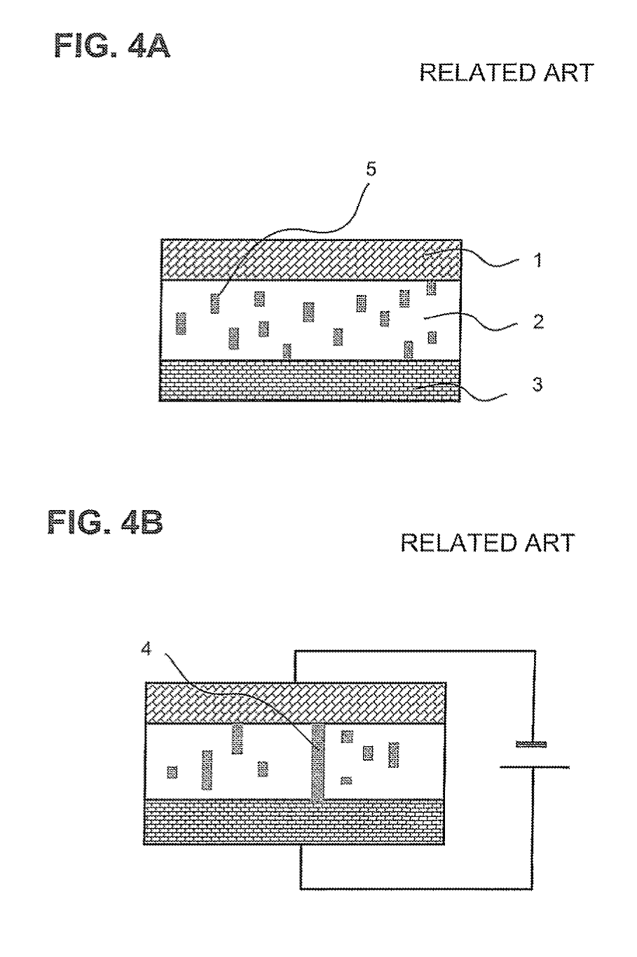

As shown in FIG. 4A, a transition metal oxide thin film (2), in which there are uniformly contained oxygen deficiencies or metal deficiencies (5), is formed. An electric field is then applied to this thin film (2) via the upper electrode (1) and the lower electrode (3), as shown in FIG. 4B. By so doing, oxygen or metal is diffused or precipitated via oxygen deficiencies or metal deficiencies in the transition metal oxide film (2), thus forming a current path (filament) (4) which is capable of electron-conduction or hole conduction between the upper and lower electrodes (1, 3). The electric field is then applied to cause the current to flow. The filament (4), formed by metal precipitation, is then re-oxidized, or the filament (4), formed by the metal deficiencies is re-filled with metal, thereby rupturing the current path. Resistance change of the transition metal oxide may occur due to the repetition of the phenomenon described above.

In Patent Document 1 and in Non-Patent Document 2, there is disclosed a variable resistance memory device that uses the nickel oxide as a metal oxide layer.

In general, the composition ratio of Ni and O in nickel oxide NiO is 1:1 in terms of the stoichiometric composition. However, the composition ratio of O is slightly higher because of Ni deficiencies.

A filament, formed in the nickel oxide, is Ni deficiencies precipitated. A current path by hole conduction is formed.

By controlling the amounts of the oxygen deficiencies and metal deficiencies in the transition metal oxide, it becomes possible to manufacture a variable resistance material in which filament formation and improvement of device reliability may be achieved simultaneously.

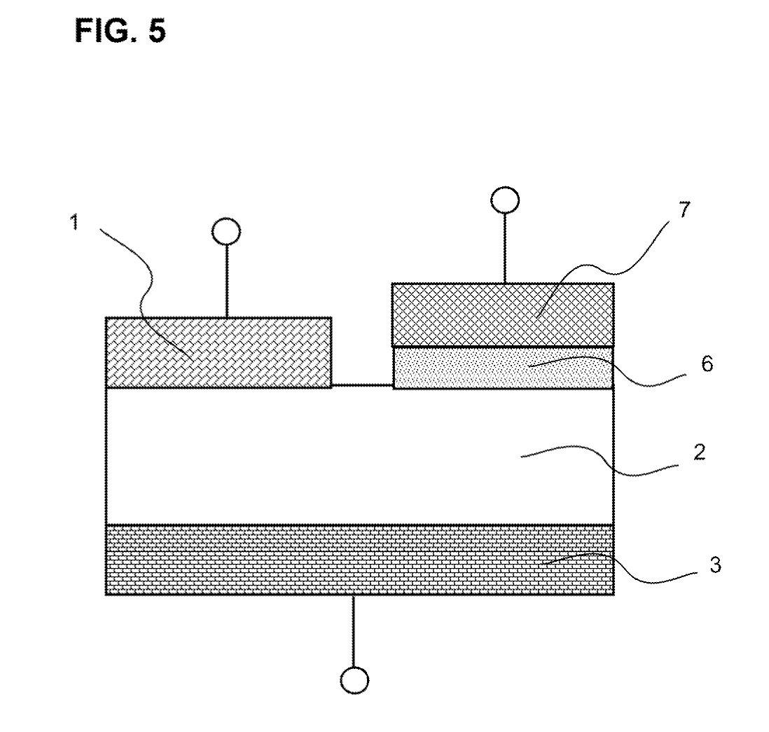

FIG. 5 schematically depicts a cross-sectional structure of the most basic element of a semiconductor memory device according to an exemplary embodiment of the present invention. According to the present invention, there is provided a non-volatile semiconductor memory device of the MIM variable resistance type with a metal/variable resistance material/metal structure including a metal oxide sandwiched between the electrodes. The non-volatile semiconductor memory device includes a lower electrode 3 formed on a semiconductor substrate, an insulating substrate or on an inter-layer insulating film of LSI interconnects, a variable resistance material 2 formed on the lower electrode 3 and including a transition metal oxide as a main component, an upper electrode I formed on the variable resistance material 2, an insulating film 6 formed so as to be contacted with the variable resistance material 2 including the transition metal oxide as a main component, and an electrode for resetting 7, also referred to as reset electrode, formed of metal and arranged on a surface of the insulating film 6. The reset electrode 7 is formed so as not to be contacted with the upper electrode 1 or with the lower electrode 3. In an example shown in FIG. 5, the reset electrode 7 is mounted in opposition to the lower electrode 3, with the variable resistance material 2 in-between. The reset electrode 7 is mounted on the insulating film 6 placed on a location on the variable resistance material 2 different from a location where the upper electrode 1 is located.

The insulating film 6, provided in-between the reset electrode 7 and the transition metal oxide film (variable resistance material 2), prevents a large current from flowing between the reset electrode 7 and the lower electrode 3 at the time of the reset operation. No current flows between the reset electrode 7 and the lower electrode 3 irrespectively of the state of the device. It is thus possible to simplify the device structure and to reduce cost and size in comparison with the case where a current control mechanism employing e.g., a MOS transistor is provided between the reset electrode 7 and the lower electrode 3.

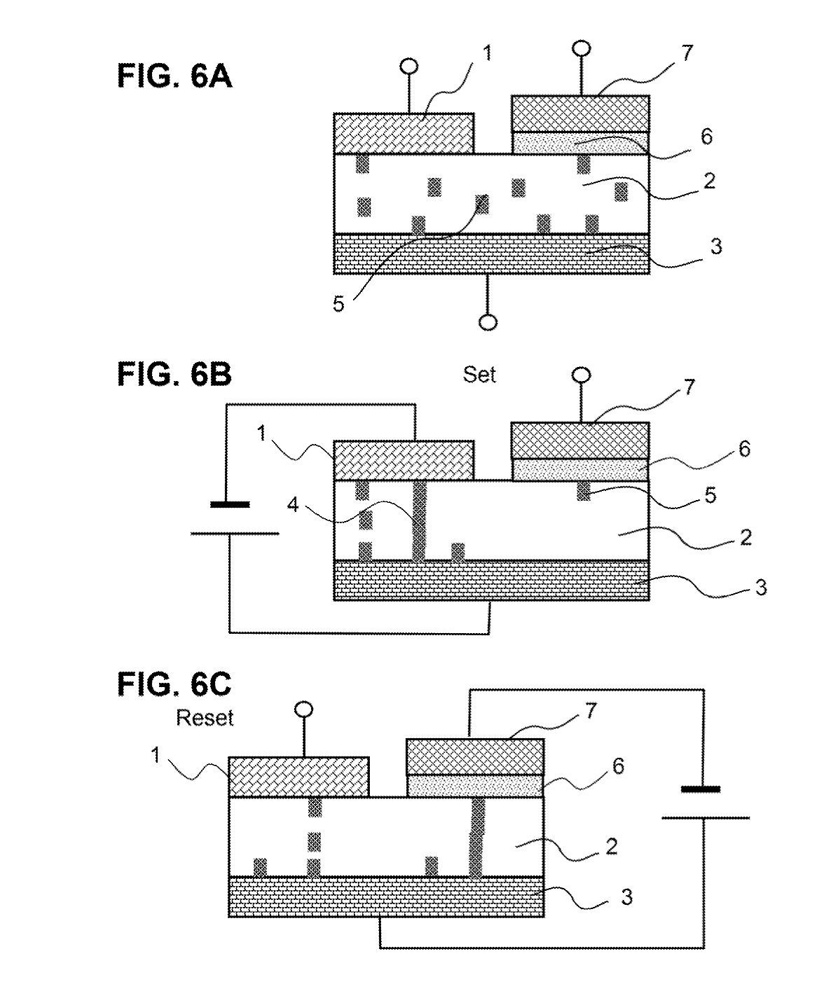

One of operating principles of the device of the present exemplary embodiment will now be described with reference to FIGS. 6A to 6C.

With reference to FIG. 6A, the MN type device is in an OFF state. Oxygen deficiencies 5 or metal deficiencies 5 are evenly contained in the transition metal oxide film which is the variable resistance material 2. It is observed that the transition metal oxide film, which is the variable resistance material 2, is sometimes denoted below as ‘transition metal oxide film 2’, with the use of the same reference numeral.

A voltage is then applied to the transition metal oxide film 2 via the upper electrode 1 and the lower electrode 3, as shown in FIG. 6B. Oxygen or metal is then diffused and precipitated in the variable resistance material 2 via the oxygen deficiencies or metal deficiencies, which are indicated by the reference numerals 5. Hence, a current path (filament) 4, capable of electron or hole conduction, is formed between the upper electrode 1 and the lower electrode 3, so that an ‘ON’ state is set.

A current control mechanism with a circuit including e.g., a MOS transistor, not shown, is provided between the upper electrode 1 and the lower electrode 3 to prevent a large current from flowing at the set time to destruct the device. The current control mechanism includes a first transistor (current source) whose output is connected to one end of a load to supply the current thereto, and a second transistor which has a drain connected to the gate of the first transistor, has a gate connected to one end of the load, and has a source connected to the other end of the load and to GND. When the large current flows from the first transistor to the load, the second transistor is turned on to cut off the large current.

Referring now to FIG. 6C, if a voltage is applied across the lower electrode 3 and the reset electrode 7 via the insulating film 6, oxygen or metal in the variable resistance material 2 is again diffused or precipitated via the oxygen deficiencies 5 or the metal deficiencies 5 in the film. Hence, the filament 4, capable of electron conduction or hole conduction, is formed between the lower electrode 3 and the reset electrode 7.

Since the insulating film 6 is provided between the reset electrode 7 and the transition metal oxide film 2, the current scarcely flows between the lower electrode 3 and the reset electrode 7.

Moreover, oxygen or metal is re-diffused through the bulk of the transition metal oxide film 2 in order to form the filament 4 between the lower electrode 3 and the reset electrode 7. Hence, the filament 4, so far formed between the upper electrode I and the lower electrode 3, is disintegrated, thus cutting off the current path 4 between the upper electrode 1 and the lower electrode 3.

Hence, an OFF state may be set between the upper electrode 1 and the lower electrode 3, even though scarcely any reset current is caused to flow between the upper electrode 1 and the lower electrode 3.

By the above-described sequence of operations, scarcely any large current needs to be caused to flow to provide for repetitive switching operations.

In the present exemplary embodiment, the upper electrode 1, lower electrode 3 and the reset electrode 7 are all formed of the same material. Alternatively, the upper electrode 1, lower electrode 3 and the reset electrode 7 may be formed of different electrode materials. The upper electrode 1, lower electrode 3 and the reset electrode 7 are preferably formed of metals selected from the group consisting of Pt, Ir, Ru, Ti, TaW and Cu, oxides and nitrides thereof

In the present exemplary embodiment, the upper electrode 1, lower electrode 3 and the reset electrode 7 may be preferably formed of metals, metal oxides or metal nitrides selected from the group consisting of Ru, RuO₂, Ti, TiN, Ta, TaN, W, WN and Cu. These electrode materials are easy to process by dry etching or CMP (Chemical Mechanical Polishing), while being high in compatibility with respect to the LSI manufacturing process.

In the present exemplary embodiment, the upper electrode 1, lower electrode 3 and the reset electrode 7 are more preferably formed of a material selected from the group consisting of Ta, TaN and Cu. These materials are used for interconnection step in the LSI manufacturing process. By using these materials, it is possible to appreciably lower the manufacturing cost needed in incorporating a semiconductor memory device to an LSI.

In the present exemplary embodiment, Cu may be most preferably used as a material for the upper electrode 1, lower electrode 3 and the reset electrode. By using Cu for the upper electrode 1, lower electrode 3 and the reset electrode, the LSI interconnection may be used as an electrode of the MIM type device. It is thus possible to reduce the resistance of the electrode to achieve performance improvement of the MIM type device and reduction of manufacturing cost simultaneously.

In the present exemplary embodiment, a SiO₂ film, a SiN film or a high dielectric constant film, for example, may be used as the insulating film 6 that isolates the variable resistance material 2 and the reset electrode 7. It is necessary to efficiently apply the voltage to the variable resistance material, while suppressing the leakage current between the transition metal oxide film 2 and the reset electrode 7. Hence, a high dielectric constant film is preferentially used as the insulating film 6. In the present exemplary embodiment, metal oxides selected from the group consisting of Ta₂O₃, HfO₂, HfSiO, ZrO, ZrSiO, LaO₂ and Al₂O₃, for example, are preferentially used as the high dielectric constant film.

In the present exemplary embodiment, HfO₂ and HfSiO are more preferentially used as the insulating film 6.

The film thickness of the insulating film 6, isolating the variable resistance material 2 and the reset electrode 7 from each other, may be set in a range from 50 nm to 1 nm. However, in view of miniaturization of the device, the film thickness may be preferentially set to less than or less equal to 20 nm and in view of ensuring reliability, the film thickness may be preferentially set to greater than or equal to 5 nm.

In the present exemplary embodiment, the main component of the variable resistance material 2 includes a transition metal oxide. An oxide of a metal selected from the group consisting of Ni, Ti, Zr, Fe, V, Mn and Co, may be used as the transition metal oxide.

In the present exemplary embodiment, Ni oxide may be preferably used as the transition metal oxide. The oxide of Ni is able to perform a switching operation irrespectively of whether it is polycrystalline or amorphous. However, an amorphous oxide of Ni may be preferably used from the perspective of a film uniformity.

Assuming that the composition of the Ni oxide is represented by NiₓO₁₋ₓ, where 0<X<1, the composition ratio X of Ni is set so that 0.4<X<0.5, for the following reason. With the NiO film, the composition ratio of O becomes slightly higher due to Ni deficiencies in the film.

By applying the voltage to this Ni film, Ni is diffused via the Ni deficiencies so that the Ni deficiencies are precipitated. A filament, a current path, may thus be formed in the nickel oxide.

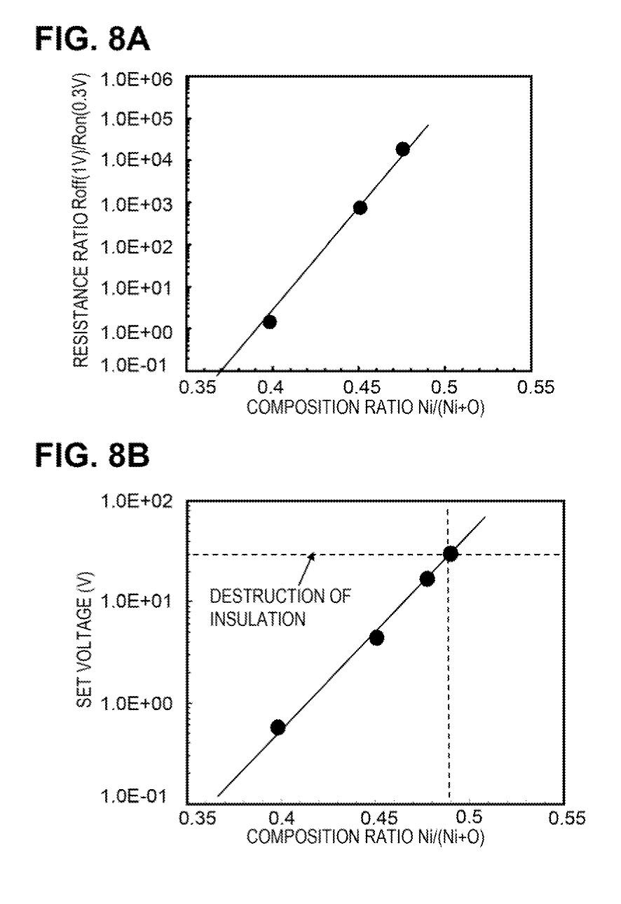

That is, referring to FIG. 8B, the more the number of Ni deficiencies, namely, the higher the composition ratio of O, the more likely it is that the filament is formed. The NiO film may thus be transferred at a lower set voltage to the ON state. If the composition of the NiO film is fully stoichiometric such that there are no Ni deficiencies in the film, the resistance change in the NiO film is not produced. In case the voltage continues to be applied to such NiO film for a set operation, dielectric breakdown will occur.

On the other hand, if there are many Ni deficiencies, the leakage current via these defects is increased, thus leading to lowering of a resistance value in an OFF state.

Thus, as shown in FIG. 8A, a sufficiently high value of the resistance ratio (Roff/Ron) for ON/OFF states becomes higher the smaller the number of Ni deficiencies, that is, the lower the composition ratio of O. In FIG. 8A, the composition ratio Ni/(Ni+O) is plotted on the horizontal axis, and the resistance ratio Roff (IV)/Ron (0.3V) is plotted on the vertical axis, using a log scale. If the Ni deficiencies are excessively present, that is, if the composition ratio of O is too high (the composition ratio of Ni is too small), the leakage current that flows before formation of the current path via Ni deficiencies distributed in the film is increased to fall into a low-resistance state. Hence, a sufficient resistance ratio for an ON/OFF states may not be obtained, such that no switching operation is allowed.

For realization of reduction of the set voltage and a high resistance ratio for ON/OFF states, in the present exemplary embodiment, it is desirable that, in the composition NiₓO₁₋ₓ for Ni oxide, where 0<X<1, X is set so that 0.42<X<0.49. It is more desirable that X, the composition ratio for Ni, is set so that 0.45<X<0.48.

In the present exemplary embodiment, the atomic density of the Ni oxide is set so as to be in a range of 5.0 to 6.3 g/cm³. If the atomic density of the Ni oxide is smaller than 5.0 g/cm³, the metals that form the upper electrode 1 and the lower electrode 3 are diffused from these electrodes into the material of the NiO film, in the course of, for example, a process for heat treatment, thus deteriorating the reliability of the NiO film. On the other hand, if the atomic density of the Ni oxide is greater than 6.3 g/cm³, distortion is produced between the NiO film and the upper electrode 1 or between the NiO film and the lower electrode 3, in the course of the process for heat treatment of the device manufacturing process. In this case, the NiO film may peel off from the lower or upper electrode.

In the present exemplary embodiment, the atomic density of the Ni oxide is more preferably set so as to be in a range of 5.5 to 6.0 g/cm³. By setting the composition and the atomic density of the Ni film to such ranges, both the filament formation and improvement in the device reliability may be achieved satisfactorily. Certain examples of the present invention will now be described.

### <EXAMPLE 1>

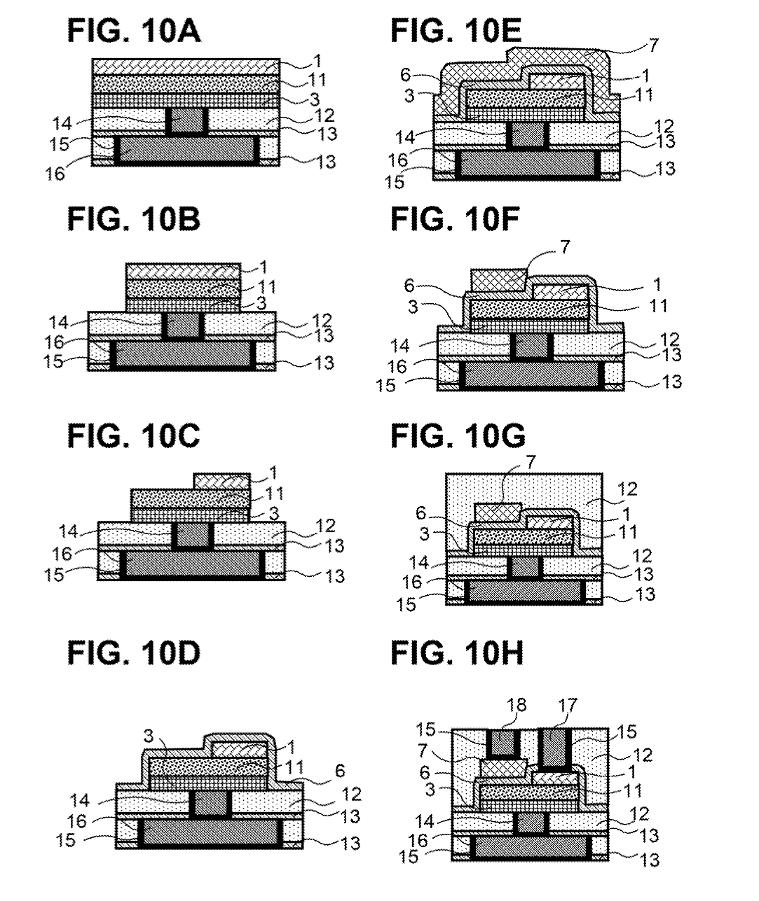

As a first example of the present invention, the structure of the most basic MIM type device is shown in FIG. 10H. FIGS. 10A to 10H are cross-sectional views illustrating the process for fabrication of a MIM type device of the present example step-by-step. More specifically, FIGS. 10A to 10H illustrate the manufacturing process for forming a MIM type device in an interconnection layer of an LSI composed of CMOS transistors.

Referring first to FIG. 10A, a lower interconnect 16 and a lower via interconnect 14 connecting to the lower interconnect 16 are formed by exploiting a CMP (Chemical Mechanical Polishing) technique and an electroplating technique. The lower interconnect 16 and the lower via interconnect 14 are formed of copper. An interlayer insulating film 12 is a silicon oxide film formed by the CVD technique.

To prevent reaction between the lower interconnect 16 and the lower via interconnect 14 on one hand and the interlayer insulating film 12 on the other hand, and peeling of the above films, an interconnect protection film 13 and an interconnect interlayer film protection film 15 are formed on interface surfaces of those films. The interconnect protection film 13 is formed of, for example, silicon carbonitride (SiCN). As the interconnect interlayer film protection film 15, a laminated film of tantalum (Ta) and tantalum nitride (TaN) is used.

After formation of the lower via interconnect 14, the surface of the lower via interconnection is exposed by CMP, in coincidence with planarization thereof.

The lower electrode 3 of the MIM memory device, a variable resistance material 11 of the present invention and the upper electrode 1 are then formed. Although the upper electrode 1 and the lower electrode 3 may be formed of different materials, these electrodes are preferably formed of the same material. Specifically, they are preferably formed of metals selected from the group consisting of Pt, Ir, Ru, Ti, TaW and Cu, oxides thereof and nitrides thereof.

In the present example, both the upper electrode 1 and the lower electrode 3 are formed of Ru for easier processing. Films of Ru for the upper electrode 1 and the lower electrode 3 may be deposited by sputtering.

The variable resistance material 11 is a NiO film. The Ni oxide may be polycrystalline or amorphous to allow for switching operations. However, from the perspective of a film uniformity, it is more preferred that the Ni oxide is amorphous.

The film thickness of the NiO film may be set within a range of 200 nm to 5 nm. However, it is preferably set to less than or equal to 100 nm from the perspective of easier processing of the device shape, and to greater than or equal to 5 nm from the perspective of a film uniformity.

More preferably, the film thickness of the NiO film is to be set to less than or equal to 60 nm from the perspective of lowering of the switching voltage, and to greater than or equal to 10 nm from the perspective of reliability.

The NiO film may be formed by sputtering. However, from the perspective of improving the denseness of the film and controllability of the composition of the film, the NiO film is preferably formed by the CVD (Chemical Vapor Polishing) method.

A material gas containing metal Ni, is adjusted in flow rate by a mass flow controller, and supplied, via a shower head, along with an oxidation gas, onto a silicon substrate heated to a predetermined temperature. This will deposit a NiO film.

As the gas of the starting material, containing a metal Ni, it is preferred to use bismethyl cyclopentane dienyl nickel ((Ni(CH3C5H4)2:(MeCp)2Ni), which is an organometallic gas. The reason is that a (MeCp)2Ni material gas may readily be decomposed at a lower temperature in a molecular oxidation gas, the amount of mixing of carbon into the NiO film deposited is extremely small, and that the density as well as the composition of the NiO film deposited may be controlled by varying the film-forming temperature.

N₂ is used as a carrier gas, while O₂ is used as an oxidation gas. A silicon wafer is heated by a heater via a susceptor. The substrate temperature is set in a range of 100° C. to 500° C. If the substrate temperature is not higher than 100° C., the material gas is decomposed just slowly to retard the film-forming rate. In addition, the uniformity in the wafer surface of the NiO film is deteriorated, thus presenting a problem related with throughput or manufacturing yield in the mass production line.

On the other hand, from the perspective of thermal resistance of the interconnect layer, it is necessary to set the substrate temperature in the course of film forming to not higher than 500° C. Further, the film density and the composition of the NiO film by the (MeCp)2Ni material gas may be controlled in dependence upon the substrate temperature.

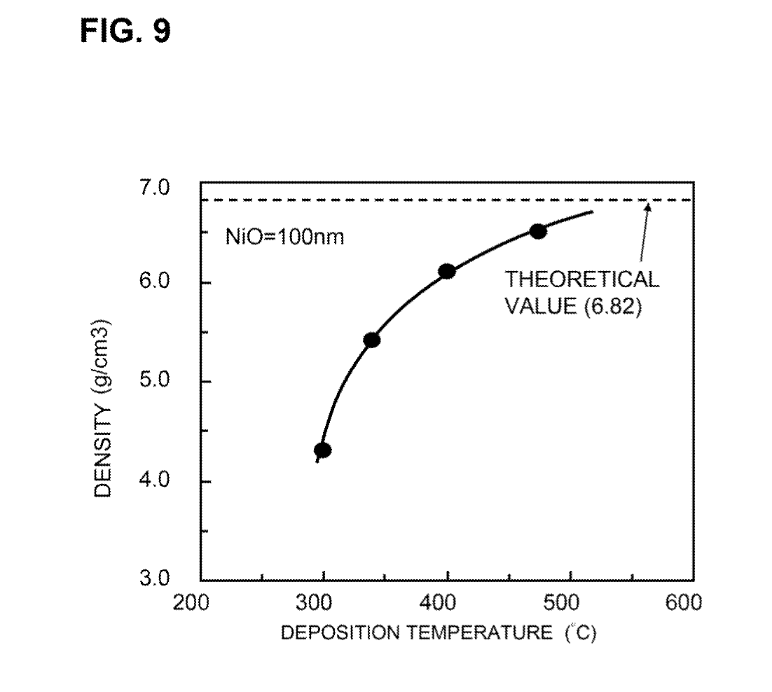

FIG. 9 shows the relationship between the deposition temperature as plotted on the vertical axis, and the density of the NiO film as plotted on the horizontal axis. It is seen that the higher the deposition temperature, the higher becomes the density of the Ni film, with the Ni film density then approaching to a theoretical value of the NiO crystal (6.82).

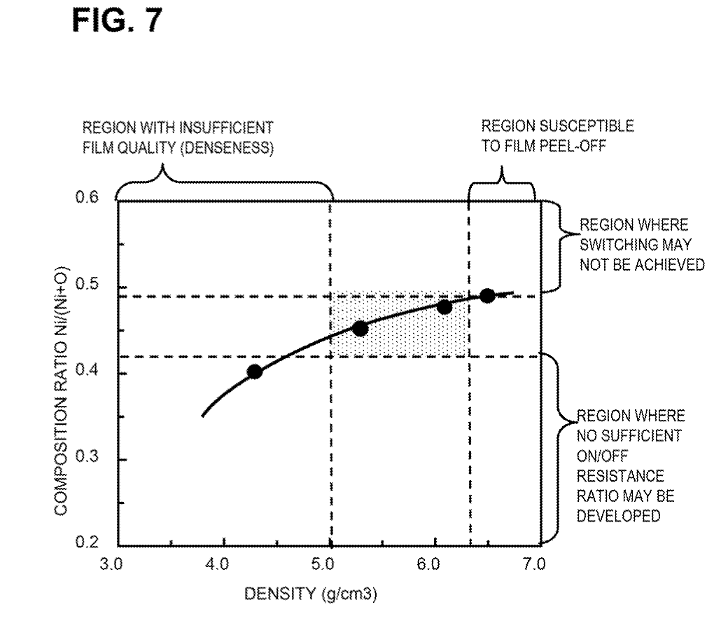

FIG. 7 shows the relationship between the composition of the NiO film by the (MeCp)2Ni material gas, as plotted on the vertical axis, and its density, as plotted on the horizontal axis. Assuming that the composition of the NiO film is represented by NiₓO₁₋ₓ (0<X<1), where the composition ratio X=Ni/(Ni+O), X is set so that 0.4<X<0.5 in order to realize the resistance variation characteristic of the NiO film. This is shown in FIG. 7 by dividing a plotting region on the graph by dashed lines into a plurality of sub-regions.

The reason is that, for 0.4≧X, the resistance ratio for an ON/OFF state that may be obtained is insufficient, and that, for X=0.5, no filament may be formed in the NiO film and dielectric breakdown is produced.

From the perspective of decreasing the set voltage and realizing a high resistance ratio for an ON/OFF state, the value of X is desirably set in a range of 0.42<X<0.49.

It is more desirable to set the composition of the NiO film so that 0.45<X<0.48.

Moreover, the atomic density of the Ni oxide is set within a range of 5.0 to 6.3 g/cm³. If the atomic density of the Ni oxide is smaller than 5.0 g/cm³, the metal that forms the upper electrode 1 and the lower electrode 3 is diffused into the bulk of the NiO film in the course of heat treatment, for example, thus deteriorating the NiO

On the other hand, if the atomic density of the Ni oxide is larger than 6.3 g/cm³, distortion between the NiO film and the upper or electrode is produced in the course of the heat treatment of the process for manufacturing the device. As a result, film peel-off may be produced between the NiO film and the upper or lower electrode.

More preferably, the above mentioned density of atoms of the Ni oxide is set in a range of 5.5 to 6.0 g/cm³.

To realize the above mentioned film density and the composition, the substrate temperature is preferably set in a range of 320° C. to 430° C. More preferably, the substrate temperature is set in a range of 350° C. to 400° C.

Preferably, the film-forming pressure may be set so as to be in a range of 0.001 Torr to 100 Torr. More preferably, the film-forming pressure may be set so as to be in a range of 1.5 Torr to 2.5 Torr.

Then, using the dry etching technique, the upper electrode 1, formed of Ru, a variable resistance material (NiO film variable resistance material layer) 11 and the lower electrode 3 of Ru, are processed to predetermined shapes, as shown in FIG. 10B.

Then, a part of the upper electrode 1 is removed by selective etching with respect to the NiO film to expose a part of the surface of the NiO film, as shown in FIG. 10C. For the selective etching, dry etching or wet etching may be used. Wet etching is preferred to avoid damaging the NiO film.

Then, as shown in FIG. 10D, the insulating film 6 for protecting the lateral side of the MIM variable resistance device and the surface of the NiO film exposed by the previous step is deposited. The insulating film 6 is to be formed of a material that is stable and that is optimum in adhesiveness to the upper electrode 1, lower electrode 3, variable resistance material 11 and the interlayer insulating film 12 of the MIM type device. A region of the insulating film 6 in contact with the variable resistance material 11 plays the role of preventing the large current from flowing between the reset electrode 7 and the lower electrode 3 during the reset operation, as described later.

The insulating film 6, isolating the variable resistance material 11 and the reset electrode 7 from each other, is formed of SiO₂, SiN or a high dielectric constant (high-K) material. From the perspective of a film uniformity, these species of the insulating film 6 are preferably formed by the CVD method or, more preferably, by an ALD (Atomic Layer Deposition) method.

To reduce the leakage current between the variable resistance material 11 and the reset electrode 7 as well as to provide for efficient voltage application, a film formed of a high dielectric constant material is preferentially used as the insulating film. As the high dielectric constant material, a metal oxide selected from the group consisting of Ta₂O₃, HfO₂, HfSiO, ZrO, ZrSiO, LaO₂ and Al₂O₃ is used. More preferably, HfO₂ or HfSiO is used.

The film thickness of the insulating film 6, isolating the variable resistance material 11 and the reset electrode 7 from each other, may be set within a range from 50 nm to 1 nm. It is preferably set so as to be less than or equal to 20 nm from the perspective of device miniaturization and so as to be greater than or equal to 5 nm from the perspective of ensuring reliability.

From the perspective of good workability, the SiN film of 10 nm, formed by the ALD method, is used in the present example.

Then, as shown in FIG. 10E, a metal film for use as the reset electrode 7 is formed on the SiN film formed by the ALD method. Although the reset electrode 7 may be formed of an electrode material different from the material for the upper electrode 1 or the lower electrode 3, the reset electrode is preferably formed of the same material as that of the upper and lower electrodes.

Similarly to the material for the upper electrode 1 and the lower electrode 3, the material for the reset electrode 7 is preferably a metal selected from the group consisting of Pt, Ir, Ru, Ti, TaW and Cu, an oxide thereof and a nitride thereof.

In the present example, the material for the reset electrode 7 is Ru, which is a material similar to the material for the upper electrode 1 and the lower electrode 3, for easier processing. Ru for the reset electrode 7 may be formed by sputtering.

Then, as shown in FIG. 10F, the Ru film is processed to a predetermined shape by dry etching to form the reset electrode 7.

Then, as shown in FIG. 10G, the interlayer insulating film 12 is formed. The interlayer insulating film 12 is a silicon oxide film deposited by the CVD technique.

Finally, contact holes are opened in the upper electrode 1 and in the reset electrode 7, as shown in FIG. 10H. An upper electrode via interconnect 18 and a reset electrode via interconnect 17 are formed by exploiting the CMP (Chemical Mechanical Polishing) technique and the electroplating technique.

### <EXAMPLE 2>

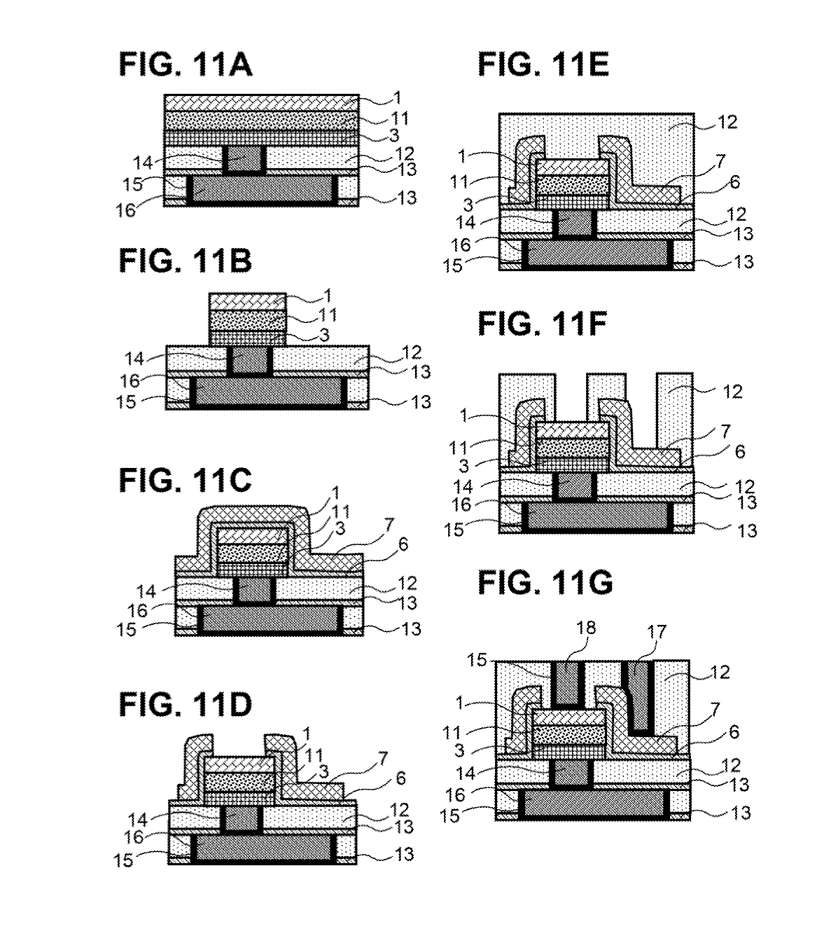

As an second example of the present invention, a structure including the reset electrode 7 on the lateral side of the MIM type device is shown in FIG. 11G

Referring to FIG. 11G, the reset electrode 7 is arranged so that a junction surface between the reset electrode 7 and the insulating film 6 and a junction surface between the insulating film 6 and the variable resistance material 11 are arranged along a lateral surface of the MIM type device, that is, in a planar direction perpendicular to the surface with which the lower electrode 3 and the upper electrode 1 are contacted with the variable resistance material 11. By so doing, the MIM type device may be miniaturized with ease. In addition, it is possible to enhance the integration density of the device and to improve the resistance ratio between the resistance for the ON state and that for the OFF state.

FIGS. 11A to 11G schematically show the cross-sections of the MIM type device of the second example of the present invention in the order of the manufacturing process steps. Specifically, FIGS. 11A to 11G show the manufacturing process of forming the MIM type device in an interconnect layer of an LSI formed by CMOS transistors.

First, referring to FIG. 11A, the lower interconnect 16 and the lower via interconnect 14 connecting thereto are formed using the CMP (Chemical Vapor Polishing) technique and the electroplating technique. These pre-stage manufacturing process steps are in common with those of the above described Example 1 and hence the description thereof is omitted.

The lower electrode 3, variable resistance material 11 and the upper electrode 1 of the MIM type device are then formed. The upper electrode 1 and the lower electrode 3 may be formed of respective different electrode materials. However, the upper electrode 1 and the lower electrode 3 are preferably formed of the same material. The electrodes 1, 3 are preferably formed of a metal selected from the group consisting of Pt, Ir, Ru, Ti, TaW and Cu, an oxide thereof and a nitride thereof.

In the present example, Ru is used as a material for the upper electrode 1 and the lower electrode 3 because of its high workability. It is noted that Ru for the upper electrode 1 and the lower electrode 3 may be deposited by sputtering.

In the present example, a NiO film is used as the variable resistance material 11. The NiO film may be formed by sputtering. However, from the perspective of improving the denseness in the film and controllability of the film composition, the NiO film is preferably formed by the CVD (Chemical Vapor Polishing) method. The manufacturing process for the NiO film by the CVD method is in common with that of the above described Example 1 and hence the description thereof is omitted.

Then, using the dry etching technique, the upper electrode 1 of Ru, variable resistance material (NiO film variable resistance layer) 11 and the lower electrode 3 of Ru are processed to predetermined shapes, as shown in FIG. 11B.

The insulating film 6, isolating the upper electrode 1, lower electrode 3 and the variable resistance material (NiO film variable resistance layer) 11 from the reset electrode 7, is deposited, as shown in FIG. 11C. A metal film for the reset electrode 7 is deposited on the insulating film 6. This insulating film 6 plays the role of isolating the upper electrode 1, lower electrode 3 and the variable resistance material (NiO film variable resistance layer) 11 from the reset electrode 7 to prevent any large current from flowing between the reset electrode on one hand and the upper and lower electrodes on the other hand.

In the present example, SiO₂, SiN or a high dielectric constant material is used as a material for the insulating film 6. For these species of the insulating film 6, preferably the CVD method, or more preferably the ALD (Atomic Layer Deposition) method, is used from the perspective of improving the denseness of the film.

It is necessary to apply the voltage efficiently as the leakage current between the variable resistance material 11 and the reset electrode 7 is suppressed. Hence, a film of a high dielectric constant material is preferably used as the insulating film 6. For the film of the high dielectric constant material, a metal oxide selected from the group consisting of Ta₂O₃, HfO₂, HfSiO, ZrO, ZrSiO, LaO₂ and Al₂O₃ is used.

In the present example, HfO₂ or HfSiO is more preferably used.

The film thickness of the insulating film 6 may be set so as to be in a range of 50 nm to 1 nm based on the setting of etching conditions. It is preferably set so as to be less than or equal to 20 nm from the perspective of miniaturization of the device size, and so as to be greater than or equal to 5 nm from the perspective of ensuring reliability.

In the present example, a SiN film, deposited by the ALD method, is used from the perspective of device miniaturization. The film thickness is set to 10 nm.

The metal film for the reset electrode 7 may be formed of an electrode material different from that of the upper electrode 1 or that of the lower electrode 3 which will be described later. Preferably, the metal film for the electrode for resetting is formed of the same material as that of the upper electrode 1 and the lower electrode 3.

Similarly to the material of the upper electrode 1 and the lower electrode 3, the material of the reset electrode 7 is preferably a metal selected from the group consisting of Pt, Ir, Ru, Ti, TaW and Cu, an oxide thereof and a nitride thereof.

In the present example, the material of the reset electrode 7 is the same material as that of the lower electrode 3, namely, Ru, for high workability.

Ru for the reset electrode 7 may be deposited by sputtering. The thickness of the metal film for the reset electrode 7 may be set in a range of 200 nm to 5 nm. It is however preferably set so as to be less than or equal to from the perspective of device miniaturization, and so as to be greater than or equal to 20 nm to secure a sufficient etching selection ratio in the next process of forming the reset electrode contact hole. In the present example, the thickness of the metal film for the reset electrode 7 is set to 50 nm.

The Ru film, namely, the metal film for the reset electrode 7, is then processed to a predetermined shape by dry etching, as shown in FIG. 11D. It is observed that the metal film for the reset electrode 7 and the insulating film 6 on the upper electrode 1 are partially removed to provide a contact hole to form an upper electrode contact in a subsequent step. Hence, although the reset electrode 7 shown appears as if it is split into left and right side sections of the MIM type device, it actually remains as-one so as to wrap the lateral sides of the MIM type device.

The interlayer insulating film 12 is then deposited, as shown in FIG. 11E.

The interlayer insulating film 12 is then partially removed in predetermined regions, using a dry etching technique, to form contact holes, as shown in FIG. 11F. The contact hole for the upper electrode 1 is opened on position registration so as not to contact with the reset electrode 7. The interlayer insulating film 12 is a silicon oxide film deposited by the CVD technique.

Finally, the upper electrode via interconnect 18 and the reset electrode via interconnect 17 are formed, using the CMP (Chemical Mechanical Polishing) technique and the electroplating technique, as shown in FIG. 11G.

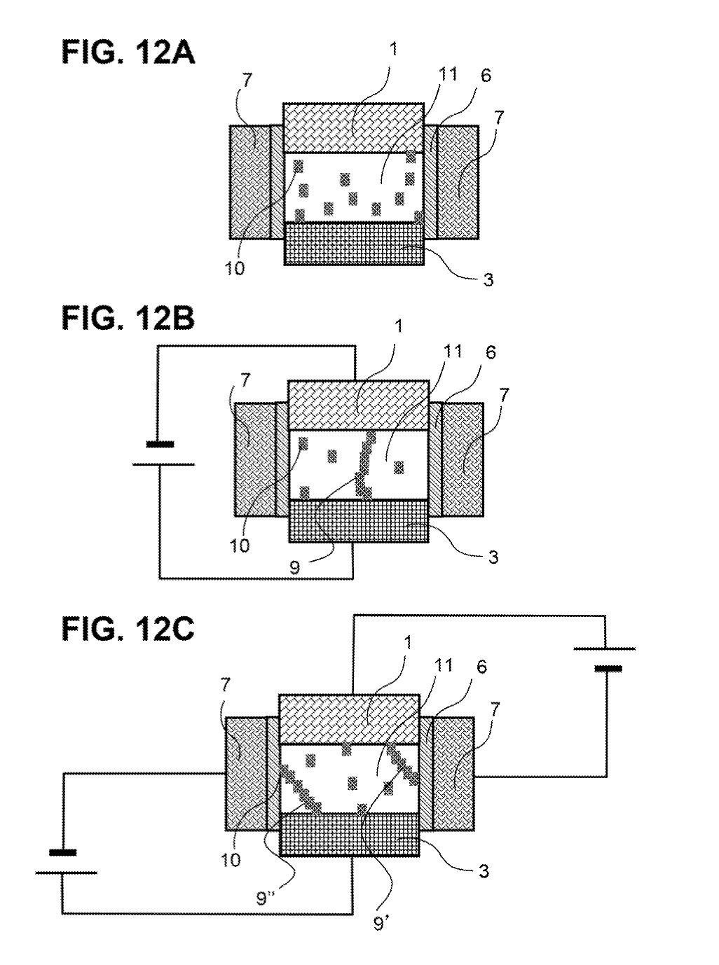

The operating principles of the MIM type device of the second example of the present invention are shown in FIGS. 12A to 12C.

Referring first to FIG. 12A, the MIM type device is OFF in an initial state. The NiO film, as the variable resistance material 11, contains Ni deficiencies 10 substantially uniformly.

If next the voltage is applied to the NiO film via the upper electrode 1 and the lower electrode 3, Ni is diffused and precipitated via the Ni deficiencies, as shown in FIG. 12B. A current path (filament) 9, capable of hole conduction, is now established between the upper electrode 1 and the lower electrode 3, so that an ON state is set. It is observed that a current limitation mechanism, not shown, composed of a circuit including a MOS transistor, is connected between the upper electrode 1 and the lower electrode 3, in a manner not shown, to prevent any large from flowing during the set time. Hence, destruction of the circuit, otherwise caused due to the large current, may be prevented from occurring.

A voltage is then applied across the lower electrode 3 and the reset electrode 7 and across the upper electrode 1 and the reset electrode 7 via the insulating film 6, as shown in FIG. 12C. The potential of the upper electrode 1 is set so as to be equal to that of the lower electrode 3. This causes re-diffusion and precipitation of Ni in the NiO film via the Ni deficiencies 10 in the film to establish current paths (filaments) 9′, 9″, capable of hole conduction between the upper electrode 1 and the reset electrode 7 or between the lower electrode 3 and the reset electrode 7. Since the insulating film 6 has been formed between the reset electrode 7 and the NiO film, scarcely any current flows between the lower electrode 3 and the reset electrode 7.

Since the current paths (filaments) 9′, 9″ have now been formed between the upper electrode 1 and the reset electrode 7 and between the lower electrode 3 and the reset electrode 7, respectively, Ni in the NiO film is re-diffused through the NiO film. Hence, the filament 9 (see FIG. 12B), so far formed between the upper electrode 1 and the lower electrode 3, is disintegrated, and hence the current path between the upper electrode 1 and the lower electrode 3 is cut off, as shown in FIG. 12C. It is thus possible to set an OFF state between the upper electrode 1 and the lower electrode 3 even though scarcely any reset current is caused to flow between the upper electrode 1 and the lower electrode 3. By this sequence of operations, electrical switching operations may repeatedly be carried out without causing any large current to flow.

### <EXAMPLE 3>

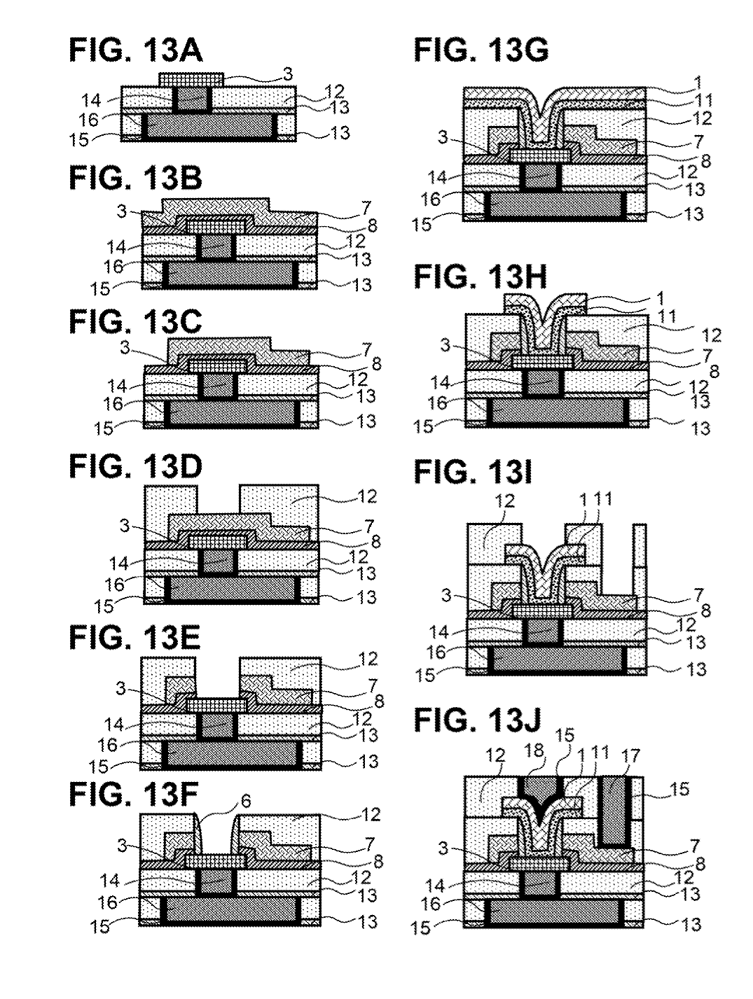

FIG. 13J shows, as a third example of the present invention. such an arrangement in which a contact hole is opened in an interlayer insulating film of LSI interconnections and in which a MIM type device is embedded in the contact hole.

Referring to FIG. 13J, the reset electrode 7 is arranged in such a manner that a junction surface between the reset electrode 7 and the insulating film 6 and a junction surface between the insulating film 6 and the variable resistance material 11 are arranged in a planar direction perpendicular to the surface with which the lower electrode 3 is contacted with the variable resistance material 11, that is, in a direction along the lateral side of the MIM type device. In addition, the lower electrode 3 and the variable resistance material 11 are embedded in the contact hole formed in the reset electrode 7. By so doing, registration exposure becomes unnecessary, while the MIM type device may be miniaturized with ease.

FIGS. 13A to 13J are cross-sectional views showing the process for fabricating the MIM type device according to an exemplary embodiment of the present invention. Specifically, FIGS. 13A to 13J are cross-sectional views showing a manufacturing process for forming a MIM type device in an interconnect layer of an LSI composed of CMOS transistors.

First, referring to FIG. 13A, a lower interconnect 16 and a lower via interconnect 14 connecting thereto are formed using the CMP (Chemical Mechanical Polishing) technique and an electroplating technique. These pre-stage manufacturing process steps are in common with those of the above described Example 1 and hence the description thereof is omitted.

The lower electrode 3 of the MIM type device is then formed on the lower via interconnect 14, and is processed to a predetermined shape by the dry etching process. Although the lower electrode 3 may be of a material different from that of the upper electrode 1, which is formed in a subsequent step, the upper electrode 1 and the lower electrode 3 are preferably formed of the same material. The upper electrode 1 and the lower electrode 3 are preferably formed of a metal selected from the group consisting of Pt, Ir, Ru, Ti, TaW and Cu, an oxide thereof and a nitride thereof.

In the present example, Ru is used as a material for the upper electrode 1 and the lower electrode 3 because of easier processing. It is noted that Ru for the upper electrode 1 and the lower electrode 3 may be deposited by sputtering.

An interlayer insulating film 8 for isolating the lower electrode 3 and the reset electrode 7 from each other is then formed, as shown in FIG. 13B. A metal film for the reset electrode 7 is formed on this interlayer insulating film 8. The interlayer insulating film 8 is formed of SiO₂ or SiN. From the perspective of uniformity, these species of the insulating film are formed preferably by the CVD method and more preferably by the ALD (Automatic Layer Deposition) method.

The film thickness of the interlayer insulating film 8 may be set so as to be in a range from 100 nm to 5 nm. It is preferably set to greater than or equal to 10 nm from the perspective of isolating the lower electrode 3 and the reset electrode 7 from each other and suppressing the leakage current, and to less than or equal to 50 nm from the perspective of device miniaturization.

In the present example, a SiO₂ film, 30 nm in thickness, deposited by the CVD method, is used.

In the present example, the metal film for the reset electrode 7 may be formed of an electrode material different from the material of the upper electrode 1, or from that of the lower electrode 3, which will be explained later. However, the upper electrode I and the lower electrode 3 are preferably formed of the same material. Similarly to the material of the upper electrode I and the lower electrode 3, the material of the reset electrode 7 is preferably formed of a metal selected from the group consisting of Pt, Ir, Ru, Ti, TaW and Cu, an oxide thereof, and a nitride thereof. In the present example, Ru is used as a material for the reset electrode because of its good workability. It is noted that Ru for the reset electrode 7 may be deposited by sputtering.

The thickness of the metal film for the reset electrode 7 may be set so as to be in a range from 200 nm to 5 nm. It is however set so as to be less than or equal to from the perspective of miniaturizing the device size and so as to be greater than or equal to 20 nm in order to allow the electric field of a sufficient strength to be applied to the variable resistance material which will be formed in a subsequent step. In the present example, the thickness of the metal film for the reset electrode 7 is set to 50 nm.

A Ru film is then processed to a predetermined shape by dry etching to form the reset electrode 7, as shown in FIG. 13C.

The interlayer insulating film 12 is then deposited as shown in FIG. 13D. A predetermined region of the interlayer insulating film 12 is removed, using the dry etching technique, thereby forming a contact hole. The interlayer insulating film 12 is a silicon oxide film deposited in accordance with the CVD technique. The metal film (reset electrode) 7 and the interlayer insulating film 8 at the bottom of the contact hole are then removed, as shown in FIG. 13E, thereby exposing the surface of the lower electrode 3 at the bottom of the contact hole.

The insulating film 6 is then formed on the surface of the interlayer insulating film 12 and within the contact hole. The so formed insulating film 6 is anisotropically etched, using the dry etching technique, thereby forming a sidewall of the insulating film 6 on the inner wall surface of the contact hole, as shown in FIG. 13F.

The sidewall, formed by this insulating film 6 performs the role of isolating the variable resistance material 11 and the reset electrode 7 from each other to prevent any large current from flowing between the reset electrode 7 and the lower electrode 3 and between the reset electrode 7 and the upper electrode 1 in the course of the reset operation. The sidewall is referred to below simply as the ‘insulating film 6’. As the insulating film 6, films of SiO₂ or SiO or a film of a high dielectric constant material is used. These species of the insulating film 6 are formed preferably by the CVD method or more preferably by the ALD (Atomic Layer Deposition) method from the perspective of providing for the film uniformity.

The insulating film 6 is preferably formed of a high dielectric constant material in consideration that the voltage needs to be applied efficiently as the leakage current between the variable resistance material 11 and the reset electrode 7 is suppressed. As the film of the high dielectric material, a metal oxide selected from the group consisting of Ta₂O₃, HfO₂, HfSiO, ZrO, ZrSiO, LaO₂ and Al₂O₃ is used. Most preferred are HfO₂ and HfSiO.

The film thickness of the insulating film 6 may be set in a range of 50 nm to 1 nm subject to particular setting of etching conditions used. Preferably, the film thickness is set to less than or equal to 20 nm from the perspective of device miniaturization and to greater than or equal to 5 nm from the perspective of ensuring reliability. With the present example, the SiN film, formed by the ALD method, is used from the perspective of ease in working operations. The film thickness of the SiN film is adjusted to 10 nm by adjusting the etching condition.

The variable resistance material 11 and the upper electrode I are then deposited, as shown in FIG. 13G. A NiO film is used for the variable resistance material 11. Although the NiO film may be formed by sputtering, it is preferably formed by the CVD (Chemical Vapor Polishing) method from the perspective of improving the denseness of the film and the filling property in the contact hole. The manufacturing process of the NiO film by the CVD method is in common with that of Example 1 and hence the description thereof is here omitted.

Then, using the dry etching technique, the upper electrode 1 and the variable resistance material 11, formed by the NiO film, are processed to predetermined shapes, as shown in FIG. 13H.

The interlayer insulating film 12 is then formed, and a contact hole is formed for the upper electrode 1, while another contact hole is formed for the reset electrode 7, as shown in FIG. 13I.

Finally, the upper electrode via interconnect 18 and the reset electrode via interconnect 17 are formed, using the CMP (Chemical Vapor Polishing) technique and the electroplating technique, as shown in FIG. 13J. By constructing the MIM type device as in the present example, the variable resistance material 11 of the MIM type device is not damaged by working by dry etching. In addition, the device size may be miniaturized with ease.

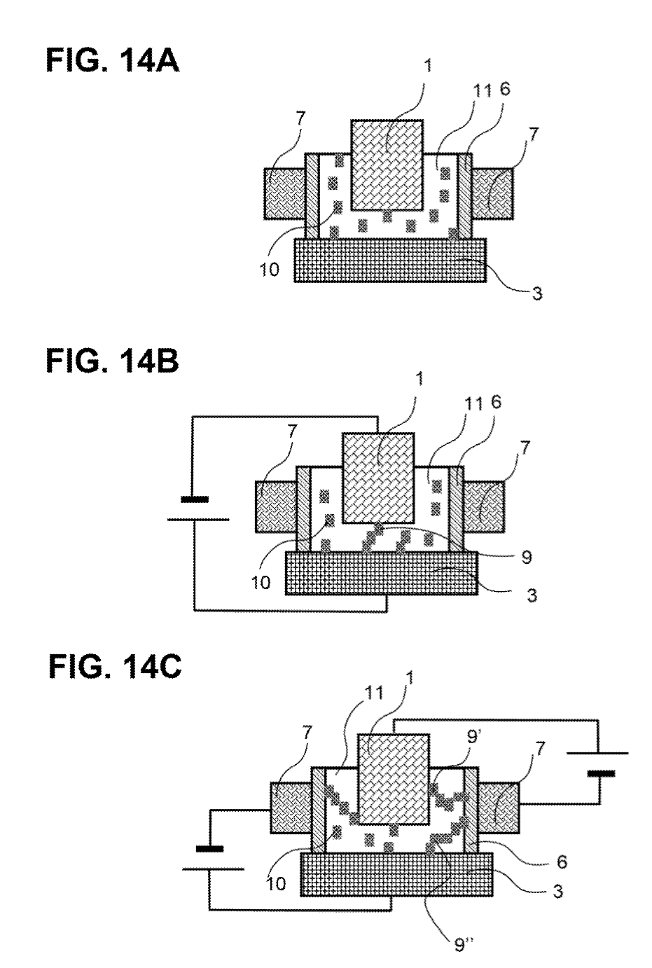

The operating principles of the MIM type device in the present example are as shown in FIGS. 14A to 14C.

First, the MIM type device is OFF in the initial state, and the NiO film, the variable resistance material 11, uniformly contains Ni deficiencies 10, as shown in FIG. 14A.

An electrical voltage is then applied to the NiO film via the upper electrode I and the lower electrode 3, as shown in FIG. 14B. Ni is now diffused and precipitated via the Ni deficiencies 10, so that a current path (filament) 9 that is capable of hole conduction is formed between the upper electrode 1 and the lower electrode 3, thus setting up an ON state. A circuit including a MOS transistor, operating as a current limiting mechanism, is connected in circuit between the upper electrode 1 and the lower electrode 3 to prevent any large from flowing during the set time to lead to destruction of the circuit.

Referring to FIG. 14C, an electrical voltage is then applied, via the insulating film 6, between the lower electrode 3 and the reset electrode 7 and between the upper electrode 1 and the reset electrode 7. The potential at the upper electrode I is set so as to be equal to that at the lower electrode 3. Then, Ni in the Ni film is precipitated on re-diffusion via the Ni deficiencies 10 in the NiO film to form the current path (filament) 9 that allowed for carrying the current by hole conduction between the upper electrode 1 or the lower electrode 3 and the reset electrode 7. Since the insulating film 6 has been formed at this time between the reset electrode 7 and the NiO film, there flows scarcely any current between the lower electrode 3 and the reset electrode 7.

Further, Ni in the NiO film is re-diffused through the film to form the filaments 9′ and 9″ between the upper electrode 1 and the reset electrode 7 and between the lower electrode 3 and the reset electrode 7, respectively. Hence, the filament 9 (see FIG. 14B) formed between the upper electrode 1 and the lower electrode 3 is disintegrated to cut off the current path between the upper electrode 1 and the lower electrode 3. This renders it possible to set an OFF state between the upper electrode 1 and the lower electrode 3 in such a manner that a reset current is scarcely caused to flow therebetween. The above sequence of operations allows repetitive switching operations without causing to any large current to flow.

The particular exemplary embodiments or examples may be modified or adjusted within the gamut of the entire disclosure of the present invention, inclusive of claims, based on the fundamental technical concept of the invention. Further, variegated combinations or selection of elements disclosed herein may be made within the framework of the claims. That is, the present invention may encompass various modifications or corrections that may occur to those skilled in the art in accordance with and within the gamut of the entire disclosure of the present invention, inclusive of claim and the technical concept of the present invention.

What is claimed is:

1. A variable resistance device comprising:
first and second electrodes arranged spaced apart from each other;
a variable resistance material including a transition metal oxide as a main component, the variable resistance material arranged to have at least one surface thereof and the other surface thereof opposite to the one surface contacted with opposing surfaces of the first electrode and the second electrode, respectively;
an insulating film arranged on the variable resistance material at a location thereof different from respective locations thereof on which the first and second electrodes are arranged, the insulating film contacted with the variable resistance material; and
a reset electrode arranged on a side of the insulating film opposite to a side thereof contacted with the variable resistance material.

2. The variable resistance device according to claim 1, wherein the first electrode is a lower electrode formed on a semiconductor substrate or an insulator substrate,
the variable resistance material is formed on the lower electrode, and
the second electrode is formed on the variable resistance material.

3. The variable resistance device according to claim 1, wherein the insulating film is arranged on a location of the other surface of the variable resistance material different from a location thereof where the second electrode is arranged,
the reset electrode being arranged on the insulating film.

4. The variable resistance device according to claim 1, wherein the insulating film is arranged in at least a partial region of a lateral surface of the variable resistance material.

5. The variable resistance device according to claim 1, wherein the second electrode is contacted with the variable resistance material both on a surface of the second electrode parallel to the surface of the first electrode contacted with the variable resistance material and on a surface of the second electrode perpendicular thereto,
the variable resistance material is contacted with the insulating film on a surface perpendicular to a contact surface of the variable resistance material and the first electrode, and
the reset electrode is contacted with a surface of the insulating film opposite to a surface of the insulating film contacted with the variable resistance material.

6. The variable resistance device according to claim 1, wherein the variable resistance material has a recess on the opposite surface thereof with respect to the one surface, with the bottom of the recess being contacted with the bottom of the second electrode, an inner wall surface of the recess being contacted with at least a part of a lateral surface of the second electrode,
the insulating film is arranged on at least a part of a lateral surface of the variable resistance material, and
the reset electrode is arranged on a side of the insulating film opposite to the side thereof contacted with the variable resistance material.

7. The variable resistance device according to claim 1, wherein the transition metal oxide includes an oxide of at least one metal selected from the group consisting of Ni, Ti, Zr, Fe, V, Mn and Co.

8. The variable resistance device according to claim 1, wherein the transition metal oxide includes Ni oxide.

9. The variable resistance device according to claim 8, wherein the composition of the Ni oxide is represented by NiₓO₁₋ₓ (0<X<1), wherein X is in a range of 0.42<X<0.49.

10. The variable resistance device according to claim 8, wherein the atomic density of the Ni oxide is in a range of 5.0 to 6.3 g/cm³.

11. A non-volatile semiconductor memory device including the variable resistance device according to claim 1, as a non-volatile memory device.

12. A method for manufacturing a variable resistance device, comprising:
forming a variable resistance material, including a transition metal oxide, on a first electrode, and forming a second electrode on the variable resistance material;
forming an insulating film on the variable resistance material at a location thereof different from respective locations thereof on which the first and second electrodes are arranged, the insulating film having one side contacted with the variable resistance material; and
forming a reset electrode on a side of the insulating film opposite to the, one side thereof contacted with the variable resistance material.

13-14. (canceled)

15. The method for manufacturing a variable resistance device according to claim 12, wherein the second electrode is formed for being contacted with the variable resistance material on a surface parallel to the surface of contact of the variable resistance material with the first electrode and on a surface perpendicular thereto,
the insulating film is formed for being contacted with the variable resistance material on a surface perpendicular to a junction surface of the variable resistance material with the first electrode, and
the reset electrode is formed for being contacted with a surface of the insulating film opposite to the surface thereof contacted with the variable resistance material.

16. The method according to claim 12, comprising the steps of:
(a) depositing a first electrode material, the variable resistance material including a transition metal oxide as a main component, and a second electrode material in this order on a substrate, and processing the first electrode material, the variable resistance material and the second electrode material to a predetermined shape;
(b) removing a part of the second electrode material to expose the surface of the variable resistance material, depositing the insulating film on the exposed surface of the variable resistance material and depositing a reset electrode material on the insulating film; and
(c) processing the reset electrode material to form a reset electrode at least in a partial region corresponding to the removed part of the second electrode material on the insulating film.

17. The method according to according to 12, comprising the steps of:
(a) depositing a first electrode material, the variable resistance material including the transition metal oxide as a main component, and a second electrode material in this order on a substrate, and processing the first electrode material, the variable resistance material and the second electrode material to a predetermined shape;
(b) depositing the insulating film for covering at least a lateral surface of the first electrode material, a lateral surface of the variable resistance material, a lateral surface of the second electrode material and a surface of the second electrode material, and further depositing a reset electrode material thereon; and
(c) removing the reset electrode material and the insulating film on the second electrode material to form an opening to expose the second electrode material.

18. A method for manufacturing a variable resistance device, comprising the steps of:
(a) forming a first electrode material on a substrate and processing the first electrode material to a predetermined shape;
(b) depositing a first insulating film and a reset electrode material to cover the first electrode material, and forming a second insulating film thereon;
(c) providing an opening in the second insulating film on the first electrode material, in the first insulating film and in the reset electrode material to expose the first electrode material;
(d) forming a third insulating film on a sidewall of the opening;
(e) forming a variable resistance material including a transition metal oxide as a main component, in contact with an exposed surface of the first electrode material in a bottom of the opening and with the third insulating film on a sidewall of the opening; and
(f) filling a second electrode material on the variable resistance material in the opening.

19-20. (canceled)

21. The method for manufacturing a variable resistance device according to claim 12, wherein the transition metal oxide includes an oxide of at least one metal selected from the group consisting of Ni, 11, Zr, Fe, V, Mn and Co.

22. The method for manufacturing a variable resistance device according to claim 12, wherein the transition metal oxide includes Ni oxide.

23. The method for manufacturing a variable resistance device according to claim 22, wherein the composition of the Ni oxide is represented by NiₓO₁₋ₓ (0<X<1), wherein X is in a range of 0.42<X<0.49.

24. The method for manufacturing a variable resistance device according to claim 22, wherein the atomic density of the Ni oxide is in a range of 5.0 to 6.3 g/cm³.

25-26. (canceled)
